(19) United States
(12) Patent Application Publication
(10) Pub. No.: US 2009/0045853 A1
(43) Pub. Date: Feb. 19, 2009

(54) TIMING CONTROLLER, DISPLAY APPARATUS HAVING THE SAME AND METHOD FOR DRIVING THE DISPLAY APPARATUS

(75) Inventor: Sang-Keun LEE, Asan-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/098,162

(22) Filed: Apr. 4, 2008

(30) Foreign Application Priority Data
Aug. 17, 2007 (KR) 10-2007-0082735

(51) Int. Cl. H03L 7/00

(52) U.S. Cl. 327/144

(57) ABSTRACT

A timing controller, a display apparatus having the timing controller and a method for driving the display apparatus, the timing controller includes a control part, an inner clock and a control signal. The control part detects whether an external clock signal and image data received from an external image apparatus are abnormal. The inner clock generating part includes a reference voltage generating circuit outputting a reference voltage independent of temperature, and generates an inner clock signal using the reference voltage. The control signal generating part generates a first driving control signal using the external clock signal and generates a second driving control signal using the inner clock signal. Accordingly, the inner clock signal that is stable with respect to the surrounding temperature and voltage variation is generated when the external clock signal and the image data are abnormal, and thus driving reliability may be enhanced.

This application claims priority to Korean Patent Application No. 2007-82735, filed on Aug. 17, 2007, and all the benefits accruing therefrom under 35 U.S.C. §119, the contents of which in its entirety are herein incorporated by reference.

### BACKGROUND OF THE INVENTION

1. Field of the Invention

The present invention relates to a timing controller, a display apparatus having the timing controller and a method for driving the display apparatus. More particularly, the present invention relates to a timing controller capable of enhancing driving reliability, a display apparatus having the timing controller and a method for driving the display apparatus.

2. Description of the Related Art

A display apparatus includes a display panel and a driving circuit driving the display panel. The driving circuit includes a timing controller performing a key role in driving the display panel. The timing controller rearranges video data transmitted from an external image apparatus, for example, a graphic card or a scaler board, and transmits the video data to a data driving circuit, so that the video data is displayed on the display panel.

The timing controller also detects whether the video data and an external clock signal that are transmitted from the external image apparatus are abnormal. The timing controller then displays the video data on the display panel based on the external clock signal transmitted from the external image apparatus, when the video data and the external clock signal are normally transmitted. However, the timing controller displays a preset error image on the display panel based on an inner clock signal generated from an inner clock generating circuit, when the video data and the external clock signal are abnormally transmitted. The preset error image is an arbitrary image informing a user of a malfunction in driving the display apparatus. An operation mode displaying the error image as mentioned above, is called a “fail-safe” mode.

In the inner clock generating circuit, as a semiconductor element that is operated in the fail-safe mode, the frequency of the inner clock signal may be destabilized by variation in a semiconductor process, such as the surrounding temperature or an unstable power source, for example.

### BRIEF SUMMARY OF THE INVENTION

The present invention has made an effort to solve the above stated problems and aspects of the present invention provides a timing controller for enhancing driving reliability, a display apparatus having the timing controller and a method for driving the display apparatus.

In an exemplary embodiment, the present invention provides a timing controller which includes a control part which detects whether an external clock signal and image data are abnormal, the external clock signal and the image data are received from an external image apparatus, an inner clock generating part and a control signal generating part. The inner clock generating part includes a reference voltage generating circuit outputting a reference voltage independent of temperature, and generates an inner clock signal using the reference voltage. The control signal generating part generates a first driving control signal using the external clock signal when the external clock signal and the image data are normal, and generates a second driving control signal using the inner clock signal when the external clock signal and the image data are abnormal.

In another exemplary embodiment, the present invention provides a display apparatus which includes a display panel, a timing controller, a gate driving part and a data driving part. The display panel includes a plurality of pixel portions electrically connected to a plurality of gate lines and a plurality of data lines, and the gate and data lines cross each other. The timing controller includes an inner clock generating part having a reference voltage generating circuit outputting a reference voltage. The timing controller generates a first driving control signal using an external clock signal when the external clock signal and image data are normal, and generates a second driving control signal using an inner clock signal generated by the inner clock generating part when the received external clock signal and the image data are abnormal. The external clock signal and the image data are received from an external image apparatus. The gate driving part generates a gate signal based on the first driving control signal or the second driving control signal, and outputs the gate signal to the gate lines. The data driving part outputs the image data received from the external image apparatus based on the first driving control signal or the second driving control signal, or preset error image data, to the data lines.

In another exemplary embodiment, the present invention provides a method for driving a display apparatus, the method includes detecting whether an external clock signal and image data is abnormal, the external clock signal and the image data are received from an external image apparatus, generating an inner clock signal is using a reference voltage independent of temperature when the external clock signal and the image data are abnormal, and displaying an error image on a display panel using the inner clock signal.

According to another exemplary embodiment of the present invention, an inner clock signal that is stable with respect to the surrounding temperature and voltage variation is generated when an external clock signal and image data are abnormal, to enhance driving reliability.

In addition, according to an exemplary embodiment, the frequency of the inner clock signal is automatically and easily determined.

### BRIEF DESCRIPTION OF THE DRAWINGS

The above and other features and advantages of the present invention will become more apparent by describing in detailed exemplary embodiments thereof with reference to the accompanying drawings, in which:

FIG. 1 is a block diagram illustrating an exemplary embodiment of a display apparatus according to the present invention;

FIG. 2 is a block diagram illustrating an exemplary embodiment of a timing controller according to the present invention;

FIG. 3 is a block diagram illustrating an exemplary embodiment of the inner clock generating part in FIG. 2, according to the present invention;

FIG. 4 is a circuit diagram illustrating an exemplary embodiment of the reference voltage generating circuit in FIG. 3, according to the present invention;

FIG. 5 is a circuit diagram illustrating another exemplary embodiment of the reference voltage generating circuit in FIG. 3, according to the present invention;

FIG. 6 is a block diagram illustrating another exemplary embodiment of a timing controller according to the present invention; and

FIG. 7 is a block diagram illustrating the inner clock generating part in FIG. 6, according to the present invention.

### BRIEF DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

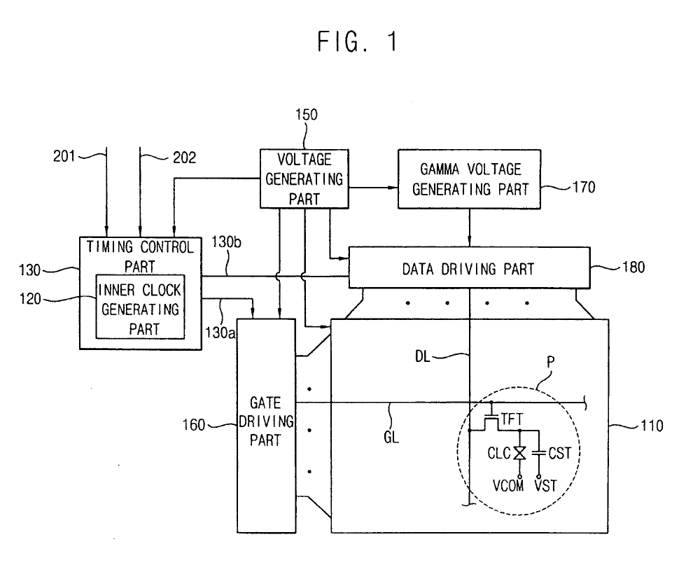

FIG. 1 is a block diagram illustrating an exemplary embodiment of a display apparatus according to the present invention.

Referring to FIG. 1, the display apparatus according to the current exemplary embodiment includes a display panel 110, a timing controller 130, a voltage generating part 150, a gate driving part 160, a gamma voltage generating part 170 and a data driving part 180.

According to an exemplary embodiment, the display panel 110 includes a plurality of data lines DL, a plurality of gate lines GL crossing the data lines DL, and a plurality of pixels P electrically connected to the data lines DL and the gate lines GL. Each of the pixels P includes a switching element TFT electrically connected to one of the gate lines GL and one of the data lines DL, a liquid crystal capacitor CLC and a storage capacitor CST. The liquid crystal capacitor CLC and the storage capacitor CST are electrically connected to the switching element TFT. According to an exemplary embodiment of the present invention, the storage capacitor CST may be omitted.

The timing controller 130 includes an inner clock generating part 120. The timing controller 130 controls the overall operation of the display apparatus.

According to an exemplary embodiment, the timing controller 130 receives an external clock signal 201 and image data 202 from an external image apparatus (not shown). The timing controller 130 detects whether the external clock signal 201 and the image data 202 are abnormal. After detecting the status of the external clock signal 201 and the image data 202, the timing controller 130 displays the image data 202 on the display panel 110 based on the external clock signal 201, when it is detected that the external clock signal 201 and the image data 202 are in a normal mode.

However, after detecting the status of the external clock signal 201 and the image data 202, the timing controller 130 performs a fail-safe mode, which displays a preset error image on the display panel 110 based on an inner clock signal generated from the inner clock generating part 120, when the external clock signal 201 and the image data 202 are abnormally inputted to the timing controller 130.

The timing controller 130 generates a driving control signal based on the external clock signal or the inner clock signal. The driving control signal includes a gate control signal 130a which controls the driving of the gate driving part 160 and a data control signal 130b which controls the driving of the data driving part 180. The gate control signal 130a includes a vertical start signal synchronized with a vertical synchronized signal and a gate clock signal. The data control signal 103b includes a horizontal start signal synchronized with a horizontal synchronized signal and a data clock signal.

The timing controller 130 rearranges the image data 202 into a data signal applied to the display panel 110, and outputs the data signal.

The inner clock generating part 120 is operated according to the control of the timing controller 130 to generate an inner clock signal having a preset frequency, when the timing controller 130 performs the fail-safe mode. According to an exemplary embodiment, the preset frequency of the inner clock signal includes approximately 40 Hz, 60 Hz, 72 Hz and so on. The inner clock generating part 120 generates the inner clock signal which is stable with respect to the surrounding temperature and voltage variation.

The voltage generating part 150 generates a driving voltage using an external voltage provided from outside, to drive the display apparatus. According to an exemplary embodiment, the driving voltage may include a gate driving voltage VON and VOFF driving the gate driving part 160, a data driving voltage VDD driving the data driving part 180, a control driving voltage VDD driving the timing controller 130, a power source voltage AVDD and a ground voltage VSS provided to the gamma voltage generating part 170, and common voltages VCOM and VST of the liquid crystal capacitor CLC and the storage capacitor CST.

According to an exemplary embodiment, the gate driving part 160 is mounted in a peripheral area surrounding a display area of the display panel 110. Alternatively, according to another exemplary embodiment, the gate driving part 160 is integrated in the peripheral area. The pixel portions P are formed in the display area, and the image is substantially displayed in the display area. The gate driving part 160 generates a gate signal and outputs the gate signal to the gate lines GL.

The gamma voltage generating part 170 generates a plurality of gamma voltages and outputs the gamma voltages to the data driving part 180. According to an exemplary embodiment, a plurality of resistors are connected in series in the gamma voltage generating part 170, and the gamma voltage generating part 170 includes a resistor string circuit. The resistor string circuit distributes the power source voltage and the ground voltage to the plurality of gamma voltages and outputs the gamma voltages.

According to one exemplary embodiment, the data driving part 180 is formed in a chip shape and is directly mounted in the peripheral area. Alternatively, according to another exemplary embodiment, the data driving part 180 is mounted on a flexible printed circuit board (“PCB”) and is mounted in the peripheral area. The data driving part 180 converts the data signal provided from the timing controller 130 into analog data display signals using the gamma voltages. The data driving part 180 outputs the data signals to the data lines DL.

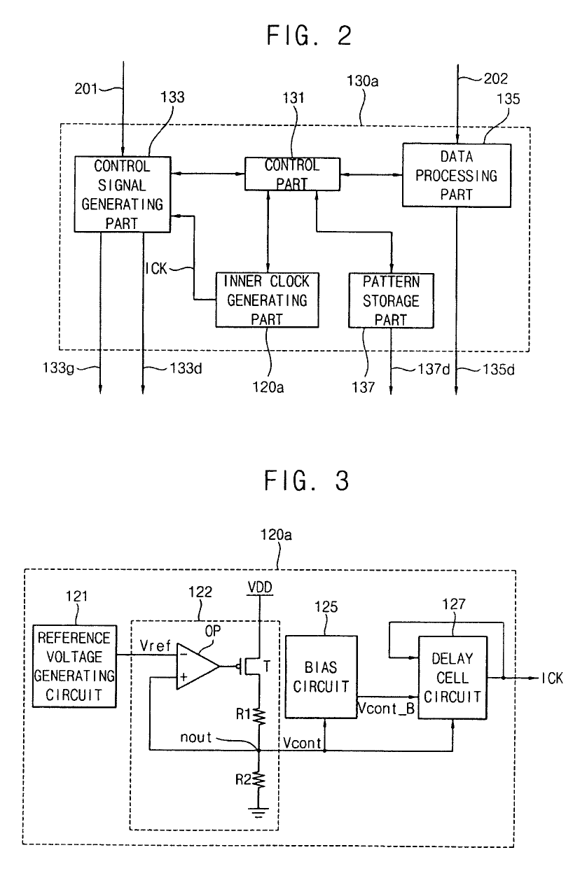

FIG. 2 is a block diagram illustrating an exemplary embodiment of a timing controller 130 according to the present invention.

Referring to FIGS. 1 and 2, the timing controller 130a includes a control part 131, a control signal generating part 133, a data processing part 135, an inner clock generating part 120a and a pattern storage part 137.

The control part 131 detects whether the external control signal 201 and the image data 202 that are received from outside are abnormal. The control part 131 drives the timing controller 130 in the normal mode when the external control signal 201 and the image data 202 are normal, and drives the timing controller 130 in the fail-safe mode when the external control signal 201 and the image data 202 are abnormal.

In the normal mode, the control signal generating part 133 generates a first driving control signal using the external control signal 201 according to a control of the control part 131. The first driving control signal includes a gate control signal 133g for driving the gate driving part 160 and a data control signal 133d for driving the data driving part 180.

The data processing part 135 converts the image data 202 into the data signal 135d corresponding to the display panel 110, and provides the data signal 135d to the data driving part 180.

In the fail-safe mode, the inner clock generating part 120a generates an inner clock signal ICK that is stable with respect to the surrounding temperature and voltage variation according to the control of the control part 131. The inner clock generating part 120a outputs the inner clock signal ICK to the control signal generating part 133. Accordingly, in the fail-safe mode, the control signal generating part 133 generates a second driving control signal using the inner clock signal ICK. According to an exemplary embodiment, the inner clock signal ICK is approximately 40 Hz, 60 Hz, 70 Hz and so on.

Error image data that is displayed on the display panel 110 in the fail-safe mode is saved to the pattern storage part 137. According to an exemplary embodiment, the error image data that is saved to the pattern storage part 137 according to the control of the control part 131 in the fail-safe mode is provided to the data driving part 180.

Accordingly, the timing controller 130 generates the first driving control signal using the external clock signal 201 in the normal mode, and displays the image data 202 on the display panel 110. The timing controller 130 generates the second driving control signal using the inner clock signal ICK in the fail-safe mode, and displays the error image data 137d on the display panel 110.

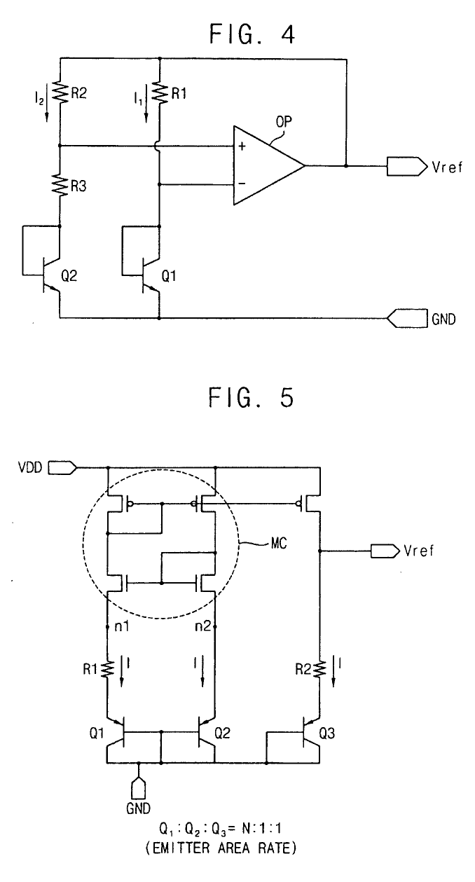

FIG. 3 is a block diagram illustrating the inner clock generating part 120a in FIG. 2. FIG. 4 is a circuit diagram illustrating an exemplary embodiment of a reference voltage generating circuit 121 in FIG. 3. FIG. 5 is a circuit diagram illustrating another exemplary embodiment of a reference voltage generating circuit 121 in FIG. 3.

Referring to FIGS. 3 and 4, the inner clock generating part 120a includes a reference voltage generating circuit 121, a buffer circuit 122, a bias circuit 125 and a delay cell circuit 127.

The reference voltage generating circuit 121, as a reference voltage source, has enhanced temperature characteristics and outputs a reference voltage Vref. In FIG. 4, the reference voltage generating circuit 121 includes a first transistor Q1, a second transistor Q2 and an operational amplifier OP.

A signal outputted from an output terminal of the operational amplifier OP is returned to an input terminal of the operational amplifier OP, so that currents I₁ and I₂ that flow in the first and second transistors Q1 and Q2, respectively, are constantly maintained. The reference voltage Vref is the sum of the voltage between both terminals of the resistor R1 and the voltage between both terminals of the first transistor Q1. According to an exemplary embodiment, the reference voltage Vref may be expressed by Equation 1.

$$Vref = {V}_{BE 1} + \frac{R 2}{R 3} \cdot Vt \cdot ln ( \frac{R 2}{R 1} ) \cdot \frac{{I}_{S 2}}{{I}_{S 1}} = {V}_{BE 1} + K \cdot Vt \qquad [ Equation 1 ]$$

In Equation 1, a symbol V_{BE1} indicates a voltage between a base and an ammeter of the first transistor Q1, a symbol Vt indicates a thermal voltage, a symbol In indicates a natural logarithm, and symbols I_{S1} and I_{S2} indicate saturation currents corresponding to I₁ and I₂, respectively.

The V_{BE1} includes a temperature coefficient inversely proportional to an absolute temperature K, and the thermal voltage Vt has a temperature coefficient directly proportional to the absolute temperature K. Thus, the reference voltage Vref independent of temperature is generated by properly controlling the absolute temperature K using different temperature coefficients.

In FIG. 5, the reference voltage generating circuit 121 includes a current mirror circuit MC, a first transistor Q1, a second transistor Q2 and a third transistor Q3.

The reference voltage generating circuit 121 includes the current mirror circuit MC, so that the current I that flows in the first, second and third transistors Q1, Q2 and Q3 is substantially the same. The current I flowing in the first transistor Q1 may be expressed by Equation 2.

$$I = N \times {I}_{S} \times exp ( \frac{{V}_{BE 1}}{Vt} ) \qquad [ Equation 2 ]$$

In Equation 2, an ammeter area ratio of the first, second and third transistors Q1, Q2 and Q3 is N:1:1, and a symbol N indicates the ammeter area ratio of the first transistor Q1. A symbol V_{BE1} indicates a voltage between a base and an ammeter of the first transistor Q1, a symbol Vt indicates a thermal voltage, and a symbol I_{S} indicates a saturation current corresponding to the current I. The reference voltage Vref may be expressed by Equation 3 using the current I.

Vref=V_{BE3}+I·R2 [Equation 3]

In Equation 3, a symbol V_{BE3} indicates a voltage between a base and an ammeter of the third transistor Q3. Accordingly, a voltage Vₙ₁ at a first node n1 connected to a first terminal of the mirror circuit MC may be expressed by Equation 4 using the current I.

$${V}_{n 1} = {V}_{BE 1} + I \cdot R 1 = Vt \times ln ( \frac{I}{N \cdot {I}_{S}} ) + I \cdot R 1 \qquad [ Equation 4 ]$$

A voltage Vₙ₂ at a second node n2 connected to a second terminal of the mirror circuit MC may be expressed by Equation 5 using the current I.

$${V}_{n 2} = {V}_{BE 2} = Vt \times ln ( \frac{I}{{I}_{S}} ) \qquad [ Equation 5 ]$$

In Equation 5, a symbol V_{BE2} indicates a voltage between a base and an ammeter of the second transistor Q2. The voltage Vₙ₁ at a first node n1 is substantially the same as the voltage Vₙ₂ at a second node n2, according to the characteristics of the mirror circuit MC. Thus, the current I may be expressed by Equation 6, combining Equation 4 and Equation 5.

$$I = \frac{1}{R 1} \times Vt \times ln ( N ) \qquad [ Equation 6 ]$$

The reference voltage Vref may be expressed by Equation 7, combining Equation 5 and Equation 6.

$$Vref = {V}_{BE 3} + \frac{R 2}{R 1} \times Vt \times ln ( N ) = {V}_{BE 3} + K \cdot Vt \qquad [ Equation 7 ]$$

In Equation 7, the V_{BE1} includes the temperature coefficient inversely proportional to the absolute temperature K, and the thermal voltage Vt includes the temperature coefficient directly proportional to the absolute temperature K. Thus, the reference voltage Vref independent of temperature may be generated by properly controlling the absolute temperature K using the different temperature coefficients.

The reference voltage Vref independent of temperature is generated using the reference voltage generating circuit 121 as illustrated in FIGS. 4 and 5.

The reference voltage generating circuit 121 provides the reference voltage Vref to the buffer circuit 122.

The buffer circuit 122 includes the operational amplifier OP, a transistor T, a first resistor R1 and a second resistor R2. The buffer circuit 122 uses the operational amplifier OP to output a constant output voltage Vcont through an output node nout in response to the reference voltage Vref. An input terminal of the buffer circuit 122 is a first input terminal of the operational amplifier OP, and a second input terminal of the operational amplifier OP is electrically connected to the output node nout.

According to an exemplary embodiment, the output terminal of the operational amplifier OP is electrically connected to a gate terminal of the transistor T, and the control driving voltage VDD is applied to a source terminal of the transistor T. A first electrode of the first resistor R1 is electrically connected to a drain terminal of the transistor T, and a second electrode of the first resistor R1 is electrically connected to the output node nout. A first electrode of the second resistor R2 is electrically connected to the output node nout, and the ground voltage is applied to a second electrode of the second resistor R2. An output terminal of the buffer circuit 122 is the output node nout electrically connected to the second electrode of the first resistor R1.

According to an exemplary embodiment, a voltage outputted by the operational amplifier OP is applied to the gate electrode of the transistor T, so that a constant current passes through the source and drain terminals of the transistor T and the buffer circuit 122 outputs the output voltage Vout according to the resistance values of the first and second resistors R1 and R2. Thus, the reference voltage Vref buffered in the buffer circuit 122 is inputted to the bias circuit 125 as the control voltage Vcont.

The bias circuit 125 generates a bias control voltage Vcont_B using the control voltage Vcont, and outputs the control voltage Vcont and the bias control voltage Vcont_B to the delay cell circuit 127.

The delay cell circuit 127 generates the inner clock signal ICK using the control voltage Vcont and the bias control voltage Vcont_B, and outputs the inner clock signal ICK.

Accordingly, the control voltage Vcont independent of the surrounding temperature is generated using the reference voltage generating circuit 121, and the control voltage Vcont that is stable with respect to voltage variation may be generated using the buffer circuit 122. Thus, the inner clock signal ICK is generated using the stable control voltage Vcon, so that a change of the frequency of the inner clock signal ICK may be decreased.

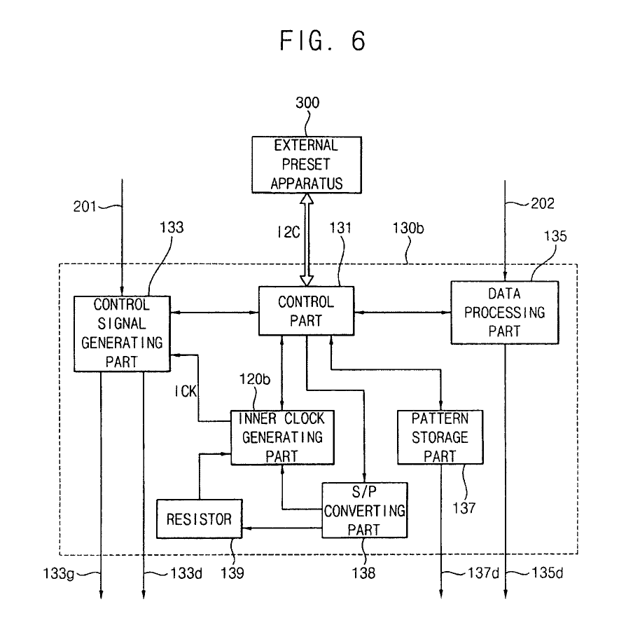

FIG. 6 is a block diagram illustrating another exemplary embodiment of a timing controller 130b according to the present invention. The timing controller 130b according to the current exemplary embodiment is substantially the same as the timing controller 130 according to the exemplary embodiment shown in FIG. 2, and thus the same reference numerals will be used to refer to the same or like parts as those described in the first example embodiment and any further repetitive explanation concerning the above elements will be omitted.

Referring to FIG. 6, the timing controller 130b includes a control part 131, a control signal generating part 133, a data processing part 135, an inner clock generating part 120b, a pattern storage part 137, a serial-to-parallel converting part 138 and a resistor 139.

The control part 131 detects whether the external control signal 201 and the image data 202 received from outside are abnormal. The control part 131 drives the timing controller 130b using the normal mode, when the external control signal 201 and the image data 202 are normal. However, the control part 131 drives the timing controller 130b using the fail-safe mode, when the external control signal 201 and the image data 202 are abnormal.

The control part 131 automatically determines the frequency of the inner clock signal ICK generated in the inner clock generating part 120b through bidirectional communication with an external preset apparatus 300. The bidirectional communication includes an inter-integrated circuit (I2C) process. The I2C process is a type of serial bidirectional communication often used in an image apparatus.

According to an exemplary embodiment, the external preset apparatus 300 operates as a master, and the control part 131 of the timing controller 130b operates as a slave. According to an exemplary embodiment, the external preset apparatus 300 is uses a field-programmable gate array (“FPGA”), a complex programmable logic device (“CPLD”), a microcontroller unit (“MCU”), a personal computer (“PC”), and other application boards.

The external preset apparatus 300 transmits preset data corresponding to the frequency of the inner clock signal ICK to the control part 131 using the I2C communication. Then, the control part 131 transmits the preset data which is transmitted through the I2C communication process and has a serial type, to the serial-to-parallel converting part 138.

The serial-to-parallel converting part 138 converts the preset data having the serial type into the preset data having a parallel type, and provides the preset data having the parallel type to the inner clock generating part 120b.

The inner clock generating part 120b generates the inner clock signal ICK having the frequency corresponding to the preset data.

The resistor 139 records the preset data provided from the serial-to-parallel converting part 138. Accordingly, when the display apparatus is driven, the preset data saved in the resistor 139 is provided to the inner clock generating part 120b, so that the inner clock signal ICK having the preset frequency is generated.

The inner clock generating part 120b may generate the inner clock signal ICK that is stable with respect to temperature variation and voltage variation in the fail-safe mode, according to the control of the control part 131. The inner clock generating part 120b may generate the inner clock signal ICK having the frequency corresponding to the preset data.

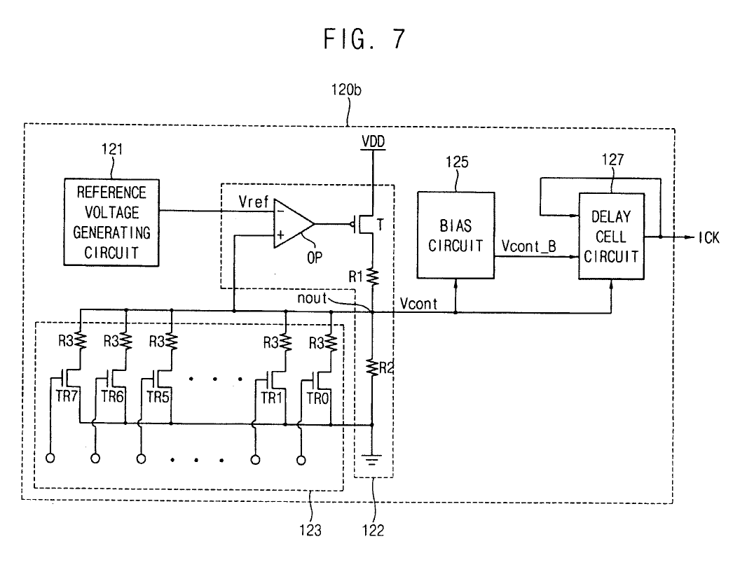

FIG. 7 is a block diagram illustrating an inner clock generating part 120b in FIG. 6.

Referring to FIGS. 6 and 7, the inner clock generating part 120b includes a reference voltage generating circuit 121, a buffer circuit 122, a switching circuit 123, a bias circuit 125 and a delay cell circuit 127.

The reference voltage generating circuit 121 is a reference voltage source enhancing the temperature characteristics and outputs the reference voltage Vref.

The buffer circuit 122 includes an operational amplifier OP, a transistor T, a first resistor R1 and a second resistor R2. The buffer circuit 122 uses the operational amplifier OP, to output a constant output voltage Vcont through an output node nout in response to the reference voltage Vref. An input terminal of the buffer circuit 122 is a first input terminal of the operational amplifier OP, and a second input terminal of the operational amplifier OP is electrically connected to the output node nout.

An output terminal of the operational amplifier OP is electrically connected to a gate terminal of the transistor T, and the control driving voltage VDD is applied to a source terminal of the transistor T. A first electrode of the first resistor R1 is electrically connected to a drain terminal of the transistor T, and a second electrode of the first resistor R1 is electrically connected to the output node nout. A first electrode of the second resistor R2 is electrically connected to the output node nout, and the ground voltage is applied to a second electrode of the second resistor R2. An output terminal of the buffer circuit 122 is the output node nout electrically connected to the second electrode of the first resistor R1.

The switching circuit 123 is electrically connected to the second input terminal of the operational amplifier OP, and is electrically connected to the second resistor R2 in parallel. According to an exemplary embodiment, the switching circuit 123 includes a plurality of third resistors R3 electrically connected to the second resistor R2 in parallel, and includes a plurality of transistors TR0, . . . , TR5, TR6 and TR7 electrically connected to the third resistors R3 in series, respectively.

First terminals of the third resistors R3 are electrically connected to the output node nout, and second terminals of the third resistors R3 are electrically connected to source terminals of the transistors TR0, . . . , TR5, TR6 and TR7, respectively. The present data is inputted to gate terminals of the transistors TR0, . . . , TR5, TR6 and TR7. The source terminals of the transistors TR0, . . . , TR5, TR6 and TR7 are electrically connected to the second terminal of the third resistor R3, and drain terminals of the transistors TR0, . . . , TR5, TR6 and TR7 are electrically connected to the ground.

Accordingly, when the preset data receives 0, the transistors TR0, . . . , TR5, TR6 and TR7 of the switching circuit 123 are turned off. When the preset data receives 1, the transistors TR0, . . . , TR5, TR6 and TR7 of the switching circuit 123 are turned on.

The level of the control voltage Vcont outputted from the output node nout of the buffer circuit 122 is controlled by the first and second resistors R1 and R2, and the third resistors R3 electrically connected to the transistors TR0, . . . , TR5, TR6 and TR7 that are turned on by the preset data.

According to an exemplary embodiment, when the preset data is 8-bit data, the preset data is inputted to the gate terminals of eight transistors TR0, . . . , TR5, TR6 and TR7. When the preset data is 1111_{—}1111, all of the transistors TR0, . . . , TR5, TR6 and TR7 are turned on, so that the third transistors R3 electrically connected to the second resistor R2 in parallel exist between the output node nout and the ground. Accordingly, the voltage at the output node nout, for example, the control voltage Vcont, may be decreased. Thus, the control voltage Vcont having a relatively small voltage is applied to the bias circuit 125.

However, when the preset data is 0000_{—}0000, all of the transistors TR0, TR5, TR6 and TR7 are turned off, so that the second resistor R2 is connected between the output node nout and the ground. Accordingly, the voltage at the output node nout, for example, the control voltage Vcont, may be increased. Thus, the control voltage Vcont having a relatively large voltage is applied to the bias circuit 125.

The preset data is controlled using the above-mentioned process, so that the frequency of the inner clock signal ICK is automatically and easily determined.

The bias circuit 125 generates a bias control voltage Vcon_B using the control voltage Vcont, and outputs the control voltage Vcont and the bias control voltage Vcont_B to the delay cell circuit 127.

The delay cell circuit 127 generates the inner clock signal ICK using the control voltage Vcont and the bias control voltage Vcont_B, and outputs the inner clock signal ICK.

Accordingly, when the control voltage Vcont having a relatively large level is applied to the bias circuit 125, the delay cell circuit 127 generates the inner clock signal ICK having a relatively large frequency. However, when the control voltage Vcont having a relatively small level is applied to the bias circuit 125, the delay cell circuit 127 generates the inner clock signal ICK having a relatively small frequency.

Thus, the level of the control voltage Vcont is controlled using the I2C communication, so that the frequency of the inner clock signal ICK may be easily determined and the frequency of the inner clock signal ICK may be variously changed.

According to an exemplary embodiment of the present invention, a voltage source of an inner clock generating circuit operated in a fail-safe mode is used for a reference voltage generating circuit, so that a reference voltage independent of temperature may be generated and a stable inner clock signal may be generated. In addition, a buffer circuit using an operational amplifier is electrically connected to an output terminal of the reference voltage generating circuit, so that a stable reference voltage may be generated. Thus, the frequency of the inner clock signal is stabilized.

In addition, a timing controller and an external preset apparatus communicate with each other using I2C communication, so that the frequency of the inner clock signal may be automatically determined within various ranges. Thus, the productivity of a display apparatus may be enhanced.

While the present invention has been shown and described with reference to some exemplary embodiments thereof, it should be understood by those of ordinary skill in the art that various changes in form and details may be made therein without departing from the spirit and the scope of the present invention as defined in the appending claims.

What is claimed is:

1. A timing controller comprising:
a control part detecting whether an external clock signal and image data are abnormal, the external clock signal and the image data being received from an external image apparatus;
an inner clock generating part comprising a reference voltage generating circuit outputting a reference voltage independent of temperature, and generating an inner clock signal using the reference voltage; and
a control signal generating part generating a first driving control signal using the external clock signal when the external clock signal and the image data are normal, and generating a second driving control signal using the inner clock signal when the external clock signal and the image data are abnormal.

2. The timing controller of claim 1, wherein the inner clock generating part comprises:
a buffer circuit stabilizing the reference voltage inputted from the reference voltage generating circuit, to generate a control voltage;
a bias circuit generating a bias control voltage using the control voltage, and outputting the control voltage and the bias control voltage; and
a delay cell circuit generating the inner clock signal using the control voltage and the bias control voltage, and outputting the inner clock signal.

3. The timing controller of claim 2, wherein the buffer circuit comprises an operational amplifier having a first input terminal to which the reference voltage is inputted and a second input terminal electrically connected to an output terminal.

4. The timing controller of claim 3, further comprising a switching circuit electrically connected to the second input terminal of the operational amplifier, and having a plurality of transistors connected in parallel with each other and a plurality of resistors respectively connected to the plurality of transistors in series.

5. The timing controller of claim 4, wherein the control part receives preset data to determine the frequency of the inner clock signal through bidirectional communication with an external preset apparatus, and the inner clock generating part determines the frequency of the inner clock signal using the preset data.

6. The timing controller of claim 5, wherein the bidirectional communication includes an inter-integrated circuit process.

7. The timing controller of claim 6, further comprising a serial-to-parallel converting part converting the received preset data having a serial type into preset data having a parallel type.

8. The timing controller of claim 5, wherein the level of the control voltage outputted from the buffer circuit is controlled by the resistors respectively connected to the transistors that are switched based on the preset data, and the delay cell circuit generates the inner clock signal using the controlled control voltage.

9. A display apparatus comprising:
a display panel comprising a plurality of pixel portions electrically connected to a plurality of gate lines and a plurality of data lines, the gate and data lines crossing each other;
a timing controller comprising an inner clock generating part having a reference voltage generating circuit outputting a reference voltage, the timing controller generating a first driving control signal using an external clock signal when the external clock signal and image data are normal, the timing controller generating a second driving control signal using an inner clock signal generated by the inner clock generating part when the external clock signal and the image data are abnormal, and the external clock signal and the image data being received from an external image apparatus;
a gate driving part generating a gate signal based on the first driving control signal or the second driving control signal, and outputting the gate signal to the gate lines; and
a data driving part outputting the image data received from the external image apparatus based on the first driving control signal or the second driving control signal, or preset error image data, to the data lines.

10. The display apparatus of claim 9, wherein the inner clock generating part comprises:
a buffer circuit stabilizing the reference voltage inputted from the reference voltage generating circuit, to generate a control voltage;
a bias circuit generating a bias control voltage using the control voltage, and outputting the control voltage and the bias control voltage; and
a delay cell circuit generating the inner clock signal using the control voltage and the bias control voltage, and outputting the inner clock signal.

11. The display apparatus of claim 10, wherein the buffer circuit comprises an operational amplifier having a first input terminal to which the reference voltage is inputted and a second input terminal electrically connected to an output terminal.

12. The display apparatus of claim 11, further comprising a switching circuit electrically connected to the second input terminal of the operational amplifier, and having a plurality of transistors connected in parallel with each other and a plurality of resistors respectively connected to the plurality of transistors in series.

13. The display apparatus of claim 12, wherein the timing controller receives preset data to determine the frequency of the inner clock signal through bidirectional communication with an external preset apparatus, and the inner clock generating part determines the frequency of the inner clock signal using the preset data.

14. The display apparatus of claim 13, wherein the bidirectional communication includes an inter-integrated circuit process.

15. The display apparatus of claim 14, further comprising a serial-to-parallel converting part converting the received preset data having a serial type into preset data having a parallel type.

16. The display apparatus of claim 15, wherein the level of the control voltage outputted from the buffer circuit is controlled by the resistors respectively connected to the transistors that are switched based on the preset data, and the delay cell circuit generates the inner clock signal using the controlled control voltage.

17. A method for driving a display apparatus, the method comprising:
detecting whether an external clock signal and image data are abnormal, the external clock signal and the image data being received from an external image apparatus;
generating an inner clock signal using a reference voltage independent of temperature when the external clock signal and the image data are abnormal; and
displaying an error image on a display panel using the inner clock signal.

18. The method of claim 17, wherein the inner clock signal is generated by:
stabilizing the reference voltage generated by a reference voltage generating circuit independent of temperature;
outputting a control voltage and a bias control voltage using the stabilized reference voltage; and
generating the inner clock signal using the control voltage and the bias control voltage.

19. The method of claim 18, wherein the level of the control voltage is controlled by preset data transmitted from an external preset apparatus, and the frequency of the inner clock signal is controlled by the level of the control voltage.

20. The method of claim 17, further comprising displaying a normal image on the display panel using the external clock signal when the external clock signal and the image data are normal.
